(19) United States
(12) Patent Application Publication
(10) Pub. No.: US 2026/0354205 A1
(43) Pub. Date: Nov. 5, 2026

(54) ELECTRIC-FIELD SHUNT FOR HYBRID BONDING INTERFACES

(71) Applicant: Applied Materials, Inc., Santa Clara, CA (US)

(72) Inventors: Seann William AYERS, Phoenix, AZ (US); She-Hwa YEN, Mountain View, CA (US)

(73) Assignee: Applied Materials, Inc., Santa Clara, CA (US)

(21) Appl. No.: 19/199,108

(22) Filed: May 5, 2025

(51) Int. Cl. H10W 42/80; H10B 80/00; H10D 80/30; H10W 20/20; H10W 80/00; H10W 90/00; H10W 90/20

(52) U.S. Cl. CPC H10W 42/80; H10B 80/00; H10W 20/20; H10W 90/00; H10D 80/30; H10W 80/312; H10W 80/327; H10W 90/20; H10W 90/297; H10W 90/792

(57) ABSTRACT

Advancements in semiconductor packaging technology have faced challenges such as signal integrity loss, parasitic capacitance, and limited interconnect density in stacked chip configurations. These challenges are addressed by introducing hybrid bonding interfaces (HBIs) and a novel grounding mechanism for through-silicon vias (TSVs). HBIs enable fine-pitch, high-density interconnects through direct metal-to-metal or dielectric-to-dielectric bonding, eliminating the need for microbumps. TSV grounding reduces the metal-insulator-semiconductor (MIS) effect by shunting electric fields to ground metal layers and ground HBIs. This grounding mechanism improves broadband return loss and insertion loss performance, mitigating parasitic effects. These advancements enhance electrical performance, reduce capacitive coupling effects, and improve signal integrity in high-speed data transfer applications.

### TECHNICAL FIELD

This disclosure generally relates to communication between components in electronic assemblies. More specifically, this disclosure describes a hybrid bonding interface between components.

### BACKGROUND

Hybrid bonding is an advanced semiconductor packaging technique that enables direct interconnects between chips by creating metal-to-metal and/or dielectric-to-dielectric bonds at the wafer or die level. Unlike traditional microbump-based bonding, hybrid bonding eliminates the need for solder, allowing for finer pitch interconnections and improved electrical and thermal performance. This process involves surface preparation, precise alignment, and the application of pressure and temperature to form a strong and reliable bond at the atomic level. Hybrid bonding is increasingly used in 3D integration, where multiple dies are stacked to enhance performance and functionality while reducing overall package size.

One key application of hybrid bonding is in high-bandwidth memory (HBM) stacks, where multiple memory dies are vertically integrated to achieve high data transfer rates. In an HBM stack, each memory die is hybrid-bonded to the one below it, creating dense, low-latency interconnects that improve bandwidth efficiency while reducing power consumption. This bonding approach allows for significantly smaller interconnect pitches compared to through-silicon vias (TSVs) and microbumps, leading to improved signal integrity and lower thermal resistance. Hybrid bonding is critical in next-generation AI accelerators, high-performance computing (HPC), and other applications requiring massive data throughput.

Despite its advantages, hybrid bonding presents challenges related to electric fields and parasitic capacitance, particularly in high-speed signaling applications. The close proximity of bonded interconnects increases the risk of capacitive coupling, which can degrade signal integrity and lead to crosstalk, noise, and increased power dissipation. Additionally, residual surface charge or unintended dielectric charging during the bonding process can create electric fields that interfere with signal transmission, potentially impacting reliability and performance. Therefore, improvements are needed in hybrid bonding technology.

### BRIEF SUMMARY

In some embodiments, an electrical interface for components in a vertical electronic assembly may include a Through-Silicon Via (TSV) including a conductive pillar and an oxide liner that surrounds the conductive pillar; a signal Hybrid-Bonding Interface (HBI) that is conductively coupled to the conductive pillar and exposed on a surface of a component; and a ground HBI that is conductively coupled to the oxide liner and exposed on the surface of the component.

In some embodiments, a method of forming an electrical interface for components in a vertical electronic assembly may include forming a TSV including a conductive pillar and an oxide liner that surrounds the conductive pillar; forming a signal HBI that is conductively coupled to the conductive pillar and exposed on a surface of a component; and forming a ground HBI that is conductively coupled to the oxide liner and exposed on the surface of the component.

In some embodiments, a vertical electronic assembly may include a first die including a a TSV with a conductive pillar and an oxide liner that surrounds the conductive pillar; a first signal HBI that is conductively coupled to the conductive pillar and exposed on a surface of the first die; and a first plurality of ground HBIs that radially surround the first signal HBI and that are conductively coupled to the oxide liner and that are exposed on the surface of the first die.

In any embodiments, any and all of the following features may be implemented in any combination and without limitation. An oxide layer may be formed on top of a silicon substrate such that the TSV extends through the silicon substrate into the oxide layer and ends in the oxide layer. A conductive shunt may conductively couple the ground HBI to the oxide liner, where the conductive shunt may couple to the oxide liner in the silicon substrate and below the oxide layer. The conductive shunt may include a vertical portion extending through the oxide layer and into the silicon substrate and a horizontal portion entirely in the silicon substrate. The signal HBI and the ground HBI may include rectangular pads adjacent to each other on the surface of the component. The ground HBI may provide a low-impedance path to dissipate an electric field generated by the metal-insulator-semiconductor (MIS) effect of the TSV. A plurality of ground

HBIs may be formed that includes the ground HBI, where each of the plurality of ground HBIs may be conductively coupled to the oxide liner and exposed on the surface of the component. The plurality of ground HBIs may be arranged to be radially symmetric around the signal HBI. The plurality of ground HBIs may be equally spaced in four quadrants around the signal HBI. The plurality of ground HBIs may include an even number of HBIs. The conductive pillar may have a width of between about 1 μm and about 4 μm. The oxide liner may have a thickness of between about 1 μm and about 2 μm. The signal HBI may have a width of between about 1 μm and about 2 μm. A pitch between the signal HBI and the ground HBI may be between about 6 μm and about 10 μm. A plurality of signal HBIs may be formed that includes the signal HBI, where each of the plurality of signal HBIs may be conductively coupled to the conductive pillar. The vertical electronic assembly may further include a second die with a second signal HBI that may be exposed on a surface of the second die; and a second plurality of ground HBIs that may radially surround the second signal HBI on the surface of the second die and that may be conductively coupled to a ground connection in the second die. The vertical electronic assembly may also include a plurality of dies including the first die, where the plurality of dies may be hybrid bonded together in a vertical stack. The plurality of dies may also form a high-bandwidth memory stack.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates an electronic assembly configured in a 2.5D package, according to some embodiments.

FIG. 2 illustrates a flowchart of a method for forming electrical interface for components in a vertical electronic assembly, according to some embodiments.

FIGS. 3A-3B illustrate top and side views of an example structure that may be formed for an HBI interface, according to some embodiments.

FIGS. 4A-4D illustrate various configurations of ground HBIs that may be formed around a conductive pillar to provide grounding for the TSV liner, according to various embodiments.

FIG. 5 illustrates an arrangement of hybrid bonding interfaces with ground HBIs, according to some embodiments.

FIG. 6 illustrates a hybrid bonding interface connection between a first die and a second die stacked vertically on top of each other, according to some embodiments.

### DETAILED DESCRIPTION

Advancements in semiconductor packaging technology have faced challenges such as signal integrity loss, parasitic capacitance, and limited interconnect density in stacked chip configurations. The invention addresses these issues by introducing hybrid bonding interfaces (HBIs) and a novel grounding mechanism for through-silicon vias (TSVs). HBIs enable fine-pitch, high-density interconnects through direct metal-to-metal and dielectric-to-dielectric bonding, while the grounding scheme shunts electric fields from TSV liners to ground using conductive pathways. These innovations improve electrical performance, reduce capacitive coupling effects, and enhance signal integrity in high-speed data transfer applications. By enabling compact, low-power, and high-bandwidth communication, the invention supports advanced semiconductor assemblies, such as high-bandwidth memory (HBM) and artificial intelligence accelerators, with improved scalability and reliability.

As semiconductor technology advances, the need for higher performance, greater power efficiency, and increased functionality has driven the development of advanced electronic packaging techniques. Vertical integration, which involves stacking or closely integrating multiple chips or functional layers, has emerged as a key strategy to enhance system performance while reducing form factor. Various approaches to vertical integration have been developed, including three-dimensional (3D) integration, two-dimensional (2D) integration, and alternative hybrid approaches.

3D integration involves stacking multiple semiconductor dies directly on top of one another, often with through-silicon vias (TSVs) or hybrid bonding to enable high-density interconnects between layers. This approach reduces interconnect length, lowers power consumption, and improves bandwidth, making it ideal for applications such as high-bandwidth memory (HBM), artificial intelligence (AI) accelerators, and high-performance computing (HPC). Three-dimensional integration also enables heterogeneous integration, where different types of semiconductor devices—such as logic, memory, and analog components—are vertically stacked to optimize performance and functionality. Similarly, 2.5D integration provides many of the benefits of 3D stacking without the complexity of through-die interconnects. One example is high-bandwidth memory (HBM) stacks connected to a central processing unit (CPU) or graphics processing unit (GPU) via a silicon interposer, allowing high-speed communication while maintaining a planar structure.

A 2.5D package for integrated circuits is an advanced semiconductor packaging technology that allows for high-bandwidth communication between multiple chips or chiplets within a single package. One of the key features of a 2.5D package is the use of an interposer, which is a passive or active substrate (e.g., silicon, organic, glass, etc.) that provides dense interconnections between the various integrated circuits. Unlike traditional printed circuit board (PCB) packaging, a 2.5D package places the interposer between the dies and the package substrate. The interposer then routes electrical signals between the dies, resulting in a much lower level of power consumption. The interposer enables integration of different types of integrated circuits, such as core processors, graphic processors, memory chips, accelerators, and so forth, within the same package. These chips can also be heterogeneous in terms of the associated semiconductor manufacturing processes (a 5 nm CPU die combined with a 7 nm CPU die). The shorter interconnect pathways compared to traditional PCB-based designs improve bandwidth, reduce signal delays, and reduce power consumption. The dense interconnect also allows for wide data buses, which may be advantageous for artificial intelligence and high-performance computing applications.

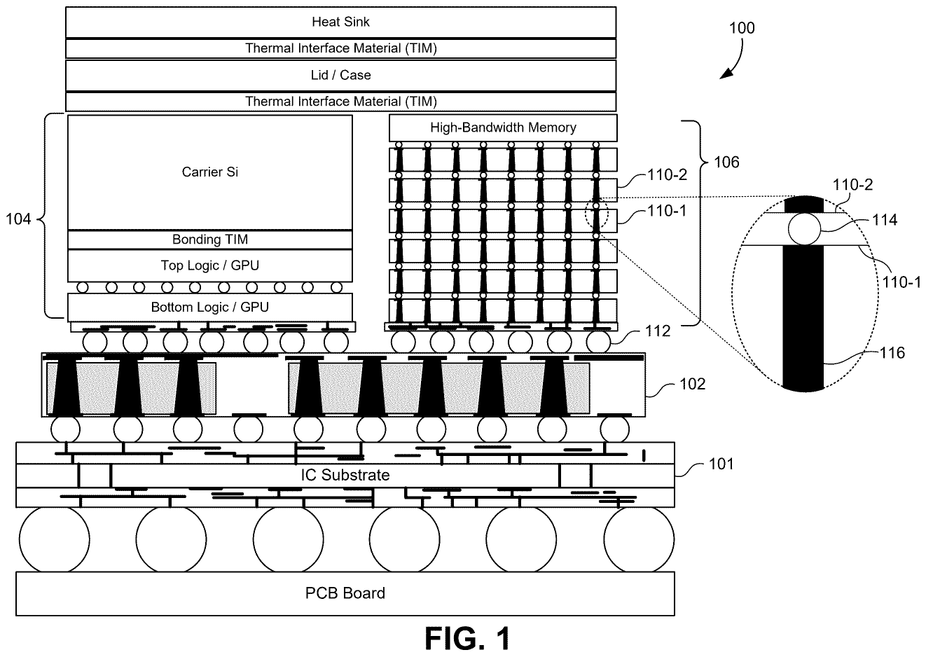

FIG. 1 illustrates an electronic assembly 100 configured in a 2.5D package, according to some embodiments. Conventional electronic packaging methods often rely on two-dimensional (2D) or three-dimensional (3D) integration techniques. However, these 2D/3D techniques may pose challenges in terms of the interconnect density within the substrates that connects various integrated circuit (IC) dies. For example, routing topologies, signal integrity, and thermal management involve difficult technical problems in existing 2D/3D packages. A 2.5D package addresses these technical problems by incorporating an interposer to facilitate communication between the IC dies.

The electronic assembly 100 may be configured as a 2.5D package that includes an interposer 102. The interposer 102 may be referred to as a redistribution layer (RDL) interposer that incorporates one or more redistribution layers for signal routing and power delivery. The interposer 102 may be fabricated from a number of different materials, including silicon, organic materials, glass, and/or the like. The interposer 102 may primarily serve as an intermediate layer between the IC dies and a printed circuit board (PCB) substrate 101, enabling high-bandwidth, low-latency communication while also reducing interconnect complexity.

The electronic assembly 100 may include any type of IC dies mounted to the interposer 102. The electronic assembly 100 includes example IC dies, such as a processor 104 and a high-bandwidth memory (HBM) 106. An HBM is a type of memory that may be stacked vertically in 2.5D/3D configurations, which allows for wider memory interfaces and higher data transfer rates than traditional memories. The HBM 106 may represent one of these HBM stacks comprising multiple DRAM chips connected through TSVs or other vertical interfaces. The processor 104 may include a high-bandwidth interface (e.g., a coherent interface, an advanced high-performance bus (AHB), etc.) designed to provide high-speed communication channels between the processor 104 and the HBM 106. Therefore, the signals being passed back and forth between the processor 104 and the HBM 106 may include contents of memory locations, memory addresses, and other memory communications. Note that the processor 104 and the HBM 106 are illustrated only by way of example and are not meant to be limiting. In other embodiments, additional IC dies may also be mounted to the interposer 102 without limitation, including systems-on-a-chip (SoCs), microcontrollers, communication ICs, accelerators, and so forth.

The HBM 106 may be comprised of a plurality of individual DRAM dies 110 that are stacked vertically to form a high-bandwidth memory stack. Each of the DRAM dies 110 represents a separate memory layer within the HBM 106, and the vertical stacking of these dies enables a compact form factor while providing high memory density and improved data transfer rates. For example, the HBM 106 may include a first DRAM die 110-1 positioned in the stack and a second DRAM die 110-2 positioned directly above the first DRAM die 110-1. Additional DRAM dies may similarly be stacked above the second DRAM die 110-2, forming a multi-layered memory structure.

The DRAM dies 110 may be electrically interconnected through vertical interconnects, such as through TSVs. These TSVs may pass through each DRAM die 110 to provide electrical communication between the stacked dies, enabling high-speed data transfers within the memory stack. For example, signals from the first DRAM die 110-1 may travel vertically through TSVs to the second DRAM die 110-2 and subsequently to additional DRAM dies higher in the stack. These TSVs also facilitate communication between the HBM 106 and the interposer 102, which routes signals between the HBM 106 and the processor 104. Each DRAM die 110 may include memory cells, control circuitry, and interfaces configured to support high-bandwidth communication. The stacked configuration of the DRAM dies 110 allows for wider memory interfaces compared to traditional memory modules, enabling the HBM 106 to achieve significantly higher data transfer rates. The precise number of DRAM dies 110 within the HBM 106 may vary depending on the specific application, but the illustrated configuration is not meant to be limiting.

FIG. 1 further illustrates a zoomed-in view 113 of a connection between the first DRAM die 110-1 and the second DRAM die 110-2 within the HBM 106. The zoomed-in view 113 highlights a vertical interconnect that enables electrical communication between the stacked DRAM dies 110. Specifically, the first DRAM die 110-1 includes a TSV 116 that extends vertically through the structure. The TSV 117 is connected to a corresponding TSV in the second DRAM die 110-2 via a microbump 114. A microbump connection is a conductive interface that electrically and mechanically links two stacked semiconductor dies, such as the DRAM dies 110. Microbumps are typically formed from solder alloys, copper, or other conductive materials and are used to connect TSVs in adjacent dies. The microbump 114 serves as the physical and electrical interface between the TSVs of the first DRAM die 110-1 and the second DRAM die 110-2. The microbump 114 may be formed from conductive materials, such as solder alloys or copper, and is configured to provide a impedance connection between the TSVs.

However, microbumps used to connect TSVs in may pose several challenges in advanced semiconductor packaging. Due to the physical size of microbumps, the pitch between adjacent connections is limited, restricting the density of interconnects that can be achieved within the stack. Additionally, microbumps may introduce electrical resistance and capacitance that degrade signal integrity, particularly in high-speed data transfer applications. The mechanical reliability of microbumps may also be compromised over time, as the solder materials used are prone to fatigue and thermal stress due to repeated heating and cooling cycles during operation. These factors, combined with challenges in fabrication and alignment during assembly, may limit the scalability and performance of microbump-based TSV connections in modern HBM designs.

As an alternative to microbumps and Hybrid Bonding Interfaces (HBI) may provide a superior alternative to microbump connections by enabling significantly smaller pitch sizes and higher interconnect densities. Hybrid bonding is an advanced semiconductor packaging technique that enables direct interconnects between chips by creating metal-to-metal and/or dielectric-to-dielectric bonds at the wafer or die level. Unlike traditional microbump-based bonding, hybrid bonding eliminates the need for solder, allowing for finer pitch interconnections and improved electrical and thermal performance. This process may involve surface preparation, precise alignment, and the application of pressure and temperature to form a strong and reliable bond at the atomic level. Hybrid bonding is increasingly used in 3D integration, where multiple dies are stacked to enhance performance and functionality while reducing overall package size.

In an HBM stack, each memory die is hybrid-bonded to the one below it, creating dense, low-latency interconnects that improve bandwidth efficiency while reducing power consumption. This bonding approach allows for significantly smaller interconnect pitches compared to microbumps, leading to improved signal integrity and lower thermal resistance.

Despite its advantages, hybrid bonding also presents challenges related to electric fields and parasitic capacitance, particularly in high-speed signaling applications. The close proximity of bonded interconnects increases the risk of capacitive coupling, which can degrade signal integrity and lead to crosstalk, noise, and increased power dissipation. Additionally, residual surface charge or unintended dielectric charging during the bonding process can create electric fields that interfere with signal transmission, potentially impacting reliability and performance. Specifically, TSVs may suffer from excessive capacitance due to the metal-insulator-semiconductor (MIS) effect inherent in their structure. This MIS capacitance arises from the insulating liner that surrounds the conductive core of the TSV, which creates an unintended capacitive coupling with the surrounding silicon substrate. As a result, TSVs may exhibit significant signal loss, reduced signal integrity, and degraded electrical performance, particularly at high frequencies. This inherent capacitive behavior makes TSVs lossy interconnects, which can limit their effectiveness in advanced semiconductor designs.

The embodiments described herein solve these and other technical problems when using HBIs and TSVs for connections between dies. Specifically, the electrical performance of TSVs may be improved by shunting the electric field to VSS (i.e., a ground connection) through the HBI and back-end-of-line (BEOL) metal layers. This configuration reduces the effective capacitance of the TSV by mitigating the MIS effect, thereby improving broadband return loss and insertion loss performance. The fine pitch achievable with HBI allows for the physical implementation of this shunting mechanism, enabling the closer integration of TSVs with BEOL ground structures. This reduction in TSV capacitance, combined with the enhanced electrical performance provided by HBI, makes it possible to achieve high-speed, high-bandwidth data transfer with improved signal integrity in advanced semiconductor assemblies.

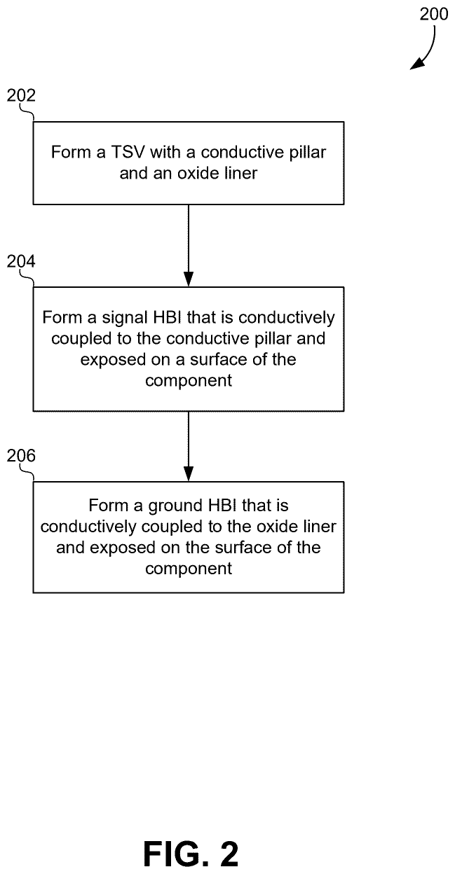

FIG. 2 illustrates a flowchart of a method 200 for forming electrical interface for components in a vertical electronic assembly, according to some embodiments. This method may be used to create semiconductor structures that connect a TSV to a hybrid bonding interface with a low-impedance path to ground to dissipate electric fields generated by the interface polarization of the oxide and silicon boundary. The small pitch of hybrid bonding interfaces (e.g., between about 6 μm about 9 μm) allows for different grounding schemes that may improve signal integrity and reduce crosstalk between transmitted signals.

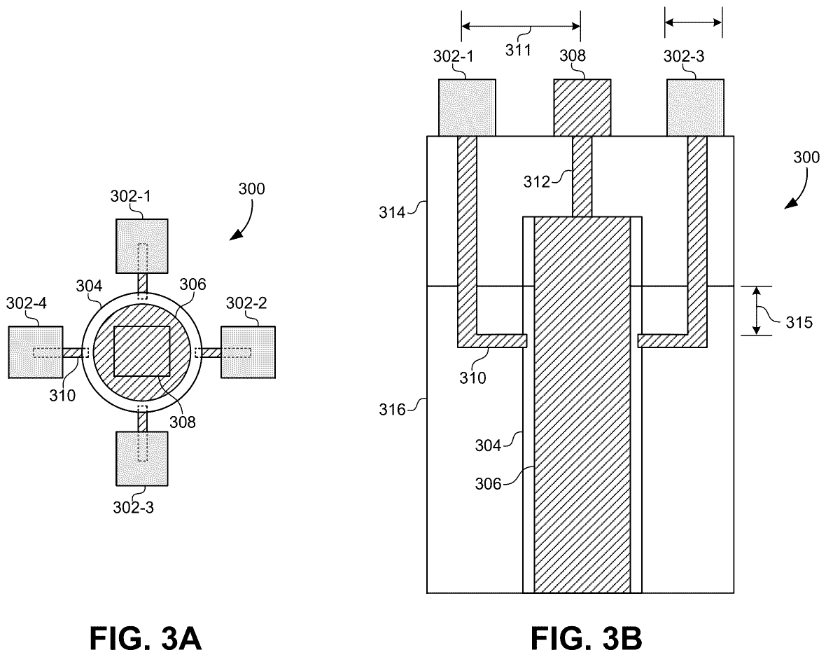

The method 200 may include forming a TSV that may include a conductive pillar and an oxide liner that may surround the conductive pillar (202). FIGS. 3A-3B illustrate top and side views of an example structure that may be formed for an HBI interface, according to some embodiments. The structures are provided only by way of example and are not meant to be limiting. Specifically, the operations performed by the method 200 may result in different structures that perform similar functions.

As illustrated in FIGS. 3A-3B, a TSV may include a conductive pillar 306 surrounded by an oxide liner 304, with the conductive pillar 306 extending vertically through a silicon substrate 316 and projecting above the top surface of the silicon substrate 316. The conductive pillar 306 may be formed from various materials, such as copper, tungsten, aluminum, or other conductive metals or alloys. The oxide liner 304 may be formed from dielectric materials, such as silicon dioxide, silicon nitride, or other insulating compounds, and may serve to electrically isolate the conductive pillar 306 from the surrounding silicon substrate 316 to reduce capacitance and leakage currents. By way of example, the conductive pillar 306 may be formed from copper, and the oxide liner 304 may be formed from silicon dioxide.

The conductive pillar 306 may be cylindrical in shape, although other geometries may also be used without limitation. A diameter of the conductive pillar 306 may be between about 1 μm and about 5 μm, depending on the design requirements and fabrication process. The oxide liner 304 may have a thickness of between about 1 μm and about 2 μm, ensuring sufficient insulation while maintaining a compact structure. The TSV may be formed using techniques such as deep reactive-ion etching (DRIE) to create a vertical hole in the silicon substrate 316, followed by deposition of the oxide liner 304 using chemical vapor deposition (CVD) or atomic layer deposition (ALD). The conductive pillar 306 may then be formed by filling the lined hole with a conductive material using processes such as electroplating, physical vapor deposition (PVD), or chemical vapor deposition.

Although FIGS. 3A-3B illustrate only the top portion of a die, it may be assumed that the TSV extends through the silicon substrate 316 from the top surface to the bottom surface of the die, enabling vertical electrical connections between different layers or components in a stacked configuration.

The silicon substrate 316 may be covered with an oxide layer 314. During manufacturing, the oxide layer 314 may be formed on top of the silicon substrate 316. The conductive pillar 306 of the TSV may extend into the oxide layer 314 by a distance of between about 5 μm and about 20 μm. The oxide layer 314 itself may have a thickness of between about 10 μm and about 30 μm, depending on the specific design requirements and application. The oxide layer 314 may comprise silicon dioxide, which is commonly used due to its insulating properties and compatibility with semiconductor processes. Alternatively, the oxide layer 314 may include other dielectric materials such as silicon nitride, aluminum oxide, or organosilicate films. The oxide layer 314 may be formed using a number of techniques. For example, a CVD process may be used where precursor gases react in a deposition chamber to deposit a thin film of oxide material over the silicon substrate 316.

The method 200 may also include forming a signal hybrid bonding interface that is conductively coupled to the conductive pillar 306 and exposed on a surface of a component (204). This hybrid bonding interface may be referred to as a signal HBI 308. The signal HBI 308 may be formed as a bonding pad positioned on the top surface of the component and may serve as an electrical interface for transmitting signals vertically to another die in a stacked electronic assembly. The signal HBI 308 may be conductively coupled to the conductive pillar 306 of the TSV through a stem 312, which provides a vertical conductive connection between the top of the conductive pillar 306 and the signal HBI 308. The stem 312 may be formed from the same conductive material as the conductive pillar 306, such as copper, tungsten, or other conductive metals. A width or diameter of the stem 312 may be less than or about equal to a width or diameter of the signal HBI 308.

The signal HBI 308 may be said to be conductively coupled to the conductive pillar 306. The term “conductively coupled,” as used herein, refers to the formation of a conductive path between two or more components through conductors (as opposed to insulators or dielectrics). The conductive path may be characterized by a total electrical resistance of less than 10 ohms, less than 5 ohms, or less than 1 ohm, depending on the embodiment, ensuring effective electrical connectivity suitable for signal transmission or power delivery. This definition may exclude any indirect coupling mediated through non-conductive materials such as insulating layers or dielectric structures. However, this definition may include multiple conductive elements that are joined together to form a conductive path, including multiple metal layers, traces, vias, solder joints, hybrid bonding connections, and so forth. Therefore, although the stem 312 is represented as a single element in FIG. 3B, the stem 312 may also be formed from a plurality of different conductive components in other embodiments.

The signal HBI 308 may be square or rectangular in shape, with dimensions between about 1 μm and about 2 μm. The signal HBI 308 may be configured to transmit electrical signals from the TSV, through the stem 312, and into the hybrid bonding interface of another vertically stacked die, thereby allowing communication with a die positioned vertically above the component in a stacked electronic assembly.

The component in which the signal HBI 308 is formed may be an HBM die, such as one of the DRAM dies in a high-bandwidth memory stack described in detail above. In such embodiments, the signal HBI 308 may enable communication between the HBM die and a processor or other integrated circuits in the assembly. Alternatively, the component may include other types of integrated circuits, such as logic dies, system-on-chip (SoC) components, accelerators, or microcontrollers. Therefore, the signal HBI 308 may be used in a variety of ICs such that this method is applicable to a wide range of advanced semiconductor packaging technologies.

The method 200 may also include forming one or more ground HBIs that are conductively coupled to the oxide liner 304 and exposed on the surface of the component (206). Each of the ground HBIs 302 may be formed as a hybrid bonding interface pad positioned on the surface of the component and may serve as an electrical grounding interface to discharge electric field from the oxide liner 304. The ground HBIs 302 may be square or rectangular in shape, with a width 313 of between about 1 μm and about 2 μm. For example, the ground HBIs 302 may have a same dimension/size as the signal HBI 308 so as to form a regular grid of evenly sized, evenly spaced hybrid bonding interfaces on the surface of the component. A pitch 311 between the hybrid bonding interfaces (including the signal HBI 308 and the ground HBIs 302) may be between about 6 μm and about 10 μm.

Each of the ground HBIs 302 may be conductively coupled to the oxide liner 304 through individual conductive shunts. For example, the conductive shunt 310 for the ground HBI 302-1 may include a vertical portion that extends from the ground HBI 302-1 through the oxide layer 314 and into the silicon substrate 316. The conductive shunt 310 may also include a horizontal portion that extends laterally from the vertical portion of the conductive shunt 310 into the oxide liner 304. The horizontal portion may be located entirely in the silicon substrate 316 such that the connection between the conductive shunt 310 and the oxide liner 304 is at a predetermined depth below the silicon substrate 316. For example, the depth 315 into the silicon substrate 316 may be greater than one micron, greater than 2 μm, greater than 5 μm, and/or greater than 10 μm. In some embodiments, the depth 315 may be as shallow is practical to reduce the mutual capacitance of the structure without allowing crosstalk to penetrate into the silicon substrate 316. The horizontal portion may contact the surface of the liner 304 or penetrate into the liner 304 by about 1 μm, ensuring effective coupling to the liner 304 for grounding purposes. While this example describes a vertical and horizontal configuration, other geometries may also be used, such as angled connections or curved structures, without limitation.

The conductive shunt 310 may be formed using various semiconductor processing techniques to ensure precise alignment and connection with the liner 304. For example, the vertical portion of the conductive shunt 310 may be created by etching a via through the oxide layer 314 using deep reactive-ion etching (DRIE) or other similar techniques, followed by filling the via with a conductive material such as copper, tungsten, or aluminum using electroplating or chemical vapor deposition (CVD). The horizontal portion may have been previously formed in the silicon substrate 316 to extend the conductive material laterally into the liner 304 using techniques such as lithography and selective etching to define the geometry of the horizontal extension, followed by deposition or metallization processes to complete the connection.

The method 200 may include forming any number of ground HBIs 402, depending on the specific design requirements and application. FIGS. 3A-3B illustrate a configuration before ground HBIs 302-1, 302-2, 302-3, and 302-4 that are equally spaced in quadrants around the conductive pillar 306. However, the “one or more ground HBIs” in operation 206 of the method 200 may include any number of ground HBIs. For example, various configurations may use one, two, three, four, six, or more ground HBIs.

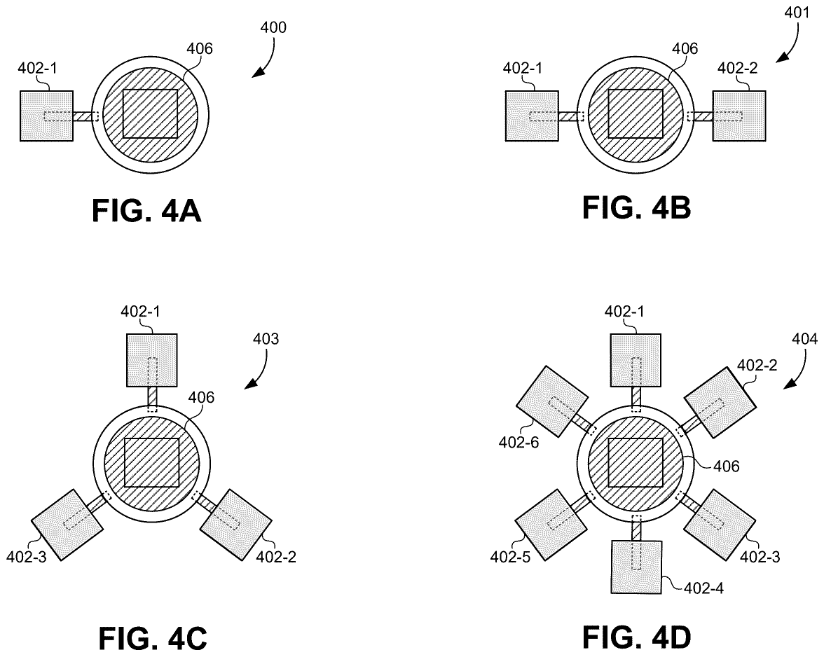

FIGS. 4A-4D illustrate various configurations of ground HBIs 402 that may be formed around a conductive pillar 406 to provide grounding for the TSV liner, according to various embodiments. For example, FIG. 4A illustrates an interface 400 that includes only a single ground HBI 402-1 positioned adjacent to the conductive pillar 406. FIG. 4B illustrates an interface 401 with two ground HBIs 402-1 and 402-2 arranged opposite each other around the conductive pillar 406, enabling balanced grounding. FIG. 4C illustrates an interface 403 with three ground HBIs 402-1, 402-2, and 402-3 that are equally spaced around the conductive pillar 406. FIG. 4D shows an interface 404 that includes six ground HBIs 402-1, 402-2, 402-3, 402-4, 402-5, and 402-6 arranged symmetrically in sextants around the conductive pillar 406. These configurations are provided only by way of example and are not meant to be limiting.

In some embodiments, the ground HBIs 402 may be evenly spaced to maintain radial symmetry around the conductive pillar 406. Radial symmetry may refer to an arrangement in which the ground HBIs 402 are evenly spaced or distributed around a central point-in this case, a center of the conductive pillar 406. Configurations with radial symmetry ensure that the ground HBIs 402 are positioned to maintain electrical and geometric balance, which can improve grounding performance and minimize parasitic effects. For example, the two ground HBIs 402-1 and 402-2 in FIG. 4B are radially symmetric, as they are spaced 180° apart and directly opposite each other around the conductive pillar 406. Similarly, the three ground HBIs 402-1, 402-2, and 402-3 in FIG. 4C form a radially symmetric configuration, as they are spaced approximately 120° apart, creating equal angular spacing. The four ground HBIs 402-1, 402-2, 402-3, and 402-4 in FIG. 4D are also radially symmetric, as they are positioned 90° apart in four quadrants around the conductive pillar 406. Some embodiments may use radial symmetry and use an even number of ground HBIs (e.g., two HBIs, four HBIs, six HBIs, and so forth).

In some embodiments, the ground HBIs 402 may be adjacent to the signal HBI on the surface of the component. The term “adjacent” in this context may mean that no other pads or HBIs are between the ground HBIs and the signal HBI on the surface of the component, and/or that these HBIs are within about 6 μm to about 10 μm of each other. The HBIs may be square or rectangular, although other geometries may also be usable in different embodiments.

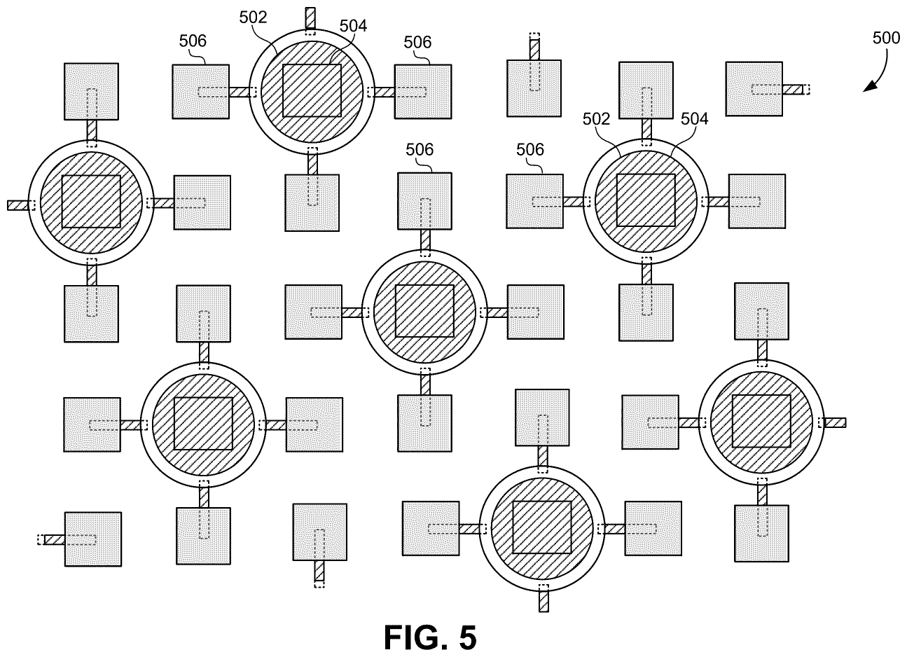

FIG. 5 illustrates an arrangement of hybrid bonding interfaces with ground HBIs, according to some embodiments. In this configuration, multiple TSVs 502 are arranged such that the signal HBIs 504 and ground HBIs 506 associated with each TSV 502 form a rectangular grid pattern. Each TSV 502 includes a signal HBI 504 positioned directly above the TSV 502 to transmit signals to vertically stacked dies, and four ground HBIs 506 are arranged symmetrically in quadrants around the signal HBI 504, as depicted in FIG. 3A. This arrangement ensures that each TSV 502 has a dedicated signal HBI 504 and sufficient grounding interfaces to maintain signal integrity and reduce parasitic capacitance during high-speed operation.

While the inclusion of multiple ground HBIs 506 for each TSV 502 requires additional hybrid bonding surfaces compared to conventional microbump interfaces, the small size and fine pitch of the HBIs allow for efficient use of surface area. The signal HBIs 504 and ground HBIs 506 may have dimensions between about 1 μm and about 2 μm, with pitches that are significantly smaller than those of traditional microbumps. This fine pitch enables the formation of tightly packed rectangular grid patterns with sufficient space to accommodate both signal HBIs 504 and multiple ground HBIs 506 for each TSV 502, even in high-density interconnect designs.

FIG. 5 illustrates only a portion of a die surface 500, and the rectangular grid pattern of TSVs 502, along with their associated signal HBIs 504 and ground HBIs 506, may extend in multiple directions across the entire surface 500 of the die. This scalable arrangement allows for the integration of additional TSVs 502 to accommodate higher interconnect densities. While FIG. 5 depicts a rectangular grid pattern for the arrangement of the TSVs 502 and their associated HBIs, alternative geometries may also be used to optimize the design for specific applications. For example, hexagonal or triangular grid patterns may be employed to achieve even greater interconnect density or to accommodate unique layout constraints. For example, these alternative geometries may be used when the TSV's 502 include different numbers of ground HBI's 506 other than four, such as three, six, and so forth, some examples of which are illustrated above in FIGS. 4A-4D. These alternative geometries provide flexibility in adapting the hybrid bonding interface arrangement to accommodate different numbers of ground HBIs 506.

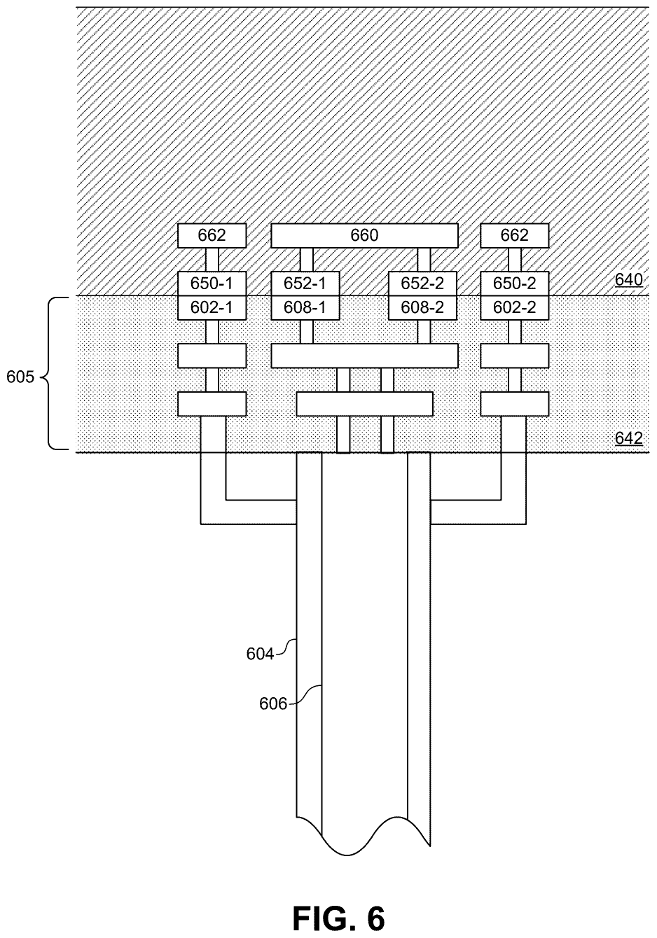

FIG. 6 illustrates a hybrid bonding interface connection between a first die 642 and a second die 640 stacked vertically on top of each other, according to some embodiments. The ground HBIs 602 on the first die 642 may be hybrid bonded to corresponding ground HBIs 650 on the second die 640, forming a robust electrical and mechanical connection within the vertical stack. The ground HBIs 650 on the second die 640 may be connected to a ground source 662, which provides electrical grounding to shut the electric field from the liner 604 around the TSV 606 in the first die 642. The ground source 662 may include a ground plane—a continuous conductive layer within the die—or other types of traces, such as dedicated metal routing paths or vias that connect to external ground pads or power delivery networks.

The first die 642 may be hybrid bonded to the second die 640 through the hybrid bonding interface, such that all corresponding HBIs are aligned and bonded to each other. For example, the signal HBIs 608 on the first die 642 may align with and bond to the signal HBIs 652 on the second die 640, enabling the transmission of signals between the stacked dies. Similarly, the ground HBIs 602 on the first die 642 may bond to the ground HBIs 650 on the second die 640 to establish a continuous grounding pathway.

A hybrid bond between the HBIs on the first die 642 and the second die 640 may be formed through a process that combines mechanical and electrical bonding. For example, the surfaces of both dies may be planarized using chemical mechanical polishing (CMP) to ensure smooth and flat bonding surfaces. The HBIs, including the signal HBIs and ground HBIs, may be prepared with exposed metal pads surrounded by dielectric material, such as silicon oxide.

The first die 642 and the second die 640 may then be aligned and brought into contact, and the hybrid bond may be formed through direct oxide bonding (mechanical adhesion) and/or metal-to-metal bonding at the HBI interfaces.

The oxide layer 314, as described in FIGS. 3A-3B, may include a number of back-end-of-line (BEOL) layers 605 that provide additional functionality and connectivity within the hybrid bonding interface. As illustrated in FIG. 6, these BEOL layers 605 may comprise multiple metal layers embedded within a dielectric material, such as silicon dioxide or other insulating compounds. Each metal layer may be patterned to form routing paths, signal splits, or ground planes, depending on the specific design requirements of the hybrid bonding interface. In some configurations, the multiple metal layers within the BEOL stack 605 may be used to split the signal from the TSV 606 into multiple signal HBIs 608 to create redundant pathways in the hybrid bonding interface. For example, the TSV 606 may be electrically coupled to one or more BEOL metal layers, which can route the signal to multiple signal HBIs 608 positioned on the surface of the component. This redundancy ensures that if one of the hybrid bonding interfaces associated with a signal HBI 608-1 fails, the signal can still be transmitted through an alternate signal HBI 608-2. Although only two signal HBIs 608 are illustrated in FIG. 6, other embodiments may use any number of signal HBIs 608.

Experimental results have shown a dramatic decrease in the electric field magnitude around the TSV when incorporating the shunt and ground HBIs in the hybrid bonding interface. In one experimental configuration, the electric field magnitude surrounding the TSV was reduced from approximately 2.40E+05 V/m to less than 1.20E+05 V/m, representing a significant suppression of the electric field. This reduction is primarily attributed to the ability of the shunt and ground HBIs 302 to effectively dissipate the electric field to the ground source, thereby mitigating the capacitive coupling effects inherent in the TSV structure.

Furthermore, incorporating the shunt and ground HBIs 302 demonstrated notable improvements in key electrical performance metrics. For example, experimental results showed a 22% reduction in return loss, improving signal integrity and reducing signal reflections during high-speed data transmission. Additionally, a 7% reduction in insertion loss was observed, enhancing the efficiency of signal propagation through the TSV. The capacitance at the liner 304 also decreased significantly, with a 30% reduction measured, further mitigating the parasitic effects associated with the MIS structure of the TSV. These experimental results highlight the effectiveness of the shunt and ground HBIs in improving the electrical performance of TSV-based interconnects in advanced semiconductor assemblies.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. An electrical interface for components in a vertical electronic assembly, the electrical interface comprising:
a Through-Silicon Via (TSV) comprising a conductive pillar and an oxide liner that surrounds the conductive pillar;
a signal Hybrid-Bonding Interface (HBI) that is conductively coupled to the conductive pillar and exposed on a surface of a component; and
a ground HBI that is conductively coupled to the oxide liner and exposed on the surface of the component.

2. The electrical interface of claim 1, further comprising an oxide layer formed on top of a silicon substrate such that the TSV extends through the silicon substrate into the oxide layer and ends in the oxide layer.

3. The electrical interface of claim 2, further comprising a conductive shunt that conductively couples the ground HBI to the oxide liner, wherein the conductive shunt couples to the oxide liner in the silicon substrate and below the oxide layer.

4. The electrical interface of claim 3, wherein the conductive shunt comprises a vertical portion extending through the oxide layer and into the silicon substrate, and a horizontal portion entirely in the silicon substrate.

5. The electrical interface of claim 1, wherein the signal HBI and the ground HBI comprise rectangular pads adjacent to each other on the surface of the component.

6. The electrical interface of claim 1, wherein the ground HBI provides a low-impedance path to dissipate an electric field generated by the metal-insulator-semiconductor (MIS) effect of the TSV.

7. A method of forming an electrical interface for components in a vertical electronic assembly, the method comprising:
forming a Through-Silicon Via (TSV) comprising a conductive pillar and an oxide liner that surrounds the conductive pillar;
forming a signal Hybrid-Bonding Interface (HBI) that is conductively coupled to the conductive pillar and exposed on a surface of a component; and
forming a ground HBI that is conductively coupled to the oxide liner and exposed on the surface of the component.

8. The method of claim 7, further comprising forming a plurality of ground HBIs that includes the ground HBI, wherein each of the plurality of ground HBIs are conductively coupled to the oxide liner and exposed on the surface of the component.

9. The method of claim 8, wherein the plurality of ground HBIs are arranged to be radially symmetric around the signal HBI.

10. The method of claim 8, wherein the plurality of ground HBIs are equally spaced in four quadrants around the signal HBI.

11. The method of claim 8, wherein the plurality of ground HBIs comprises an even number of HBIs.

12. The method of claim 7, wherein the conductive pillar has a width of between about 1 μm and about 4 μm.

13. The method of claim 7, wherein the oxide liner has a thickness of between about 1 μm and about 2 μm.

14. The method of claim 7, wherein the signal HBI has a width of between about 1 μm and about 2 μm.

15. The method of claim 7, wherein a pitch between the signal HBI and the ground HBI is between about 6 μm and about 10 μm.

16. The method of claim 7, further comprising forming a plurality of signal HBIs that includes the signal HBI, wherein each of the plurality of signal HBIs is conductively coupled to the conductive pillar.

17. A vertical electronic assembly comprising:
a first die comprising:
a Through-Silicon Via (TSV) comprising a conductive pillar and an oxide liner that surrounds the conductive pillar;
a first signal Hybrid-Bonding Interface (HBI) that is conductively coupled to the conductive pillar and exposed on a surface of the first die; and
a first plurality of ground HBIs that radially surround the first signal HBI and that are conductively coupled to the oxide liner and that are exposed on the surface of the first die.

18. The vertical electronic assembly of claim 17, further comprising:
a second die comprising:
a second signal HBI that is exposed on a surface of the second die; and
a second plurality of ground HBIs that radially surround the second signal HBI on the surface of the second die and that are conductively coupled to a ground connection in the second die.

19. The vertical electronic assembly of claim 17, further comprising a plurality of dies including the first die, wherein the plurality of dies are hybrid bonded together in a vertical stack.

20. The vertical electronic assembly of claim 17, further comprising a plurality of dies including the first die, wherein the plurality of dies form a high-bandwidth memory stack.
